(19) United States
(12) Patent Application Publication
(10) Pub. No.: US 2024/0130144 A1
(43) Pub. Date: Apr. 18, 2024

(54) SEMICONDUCTOR PACKAGE INCLUDING A THREE-DIMENSIONAL STACKED MEMORY MODULE

(71) Applicant: SAMSUNG ELECTRONICS CO., LTD., Suwon-si (KR)

(72) Inventor: Dong Joo CHOI, Suwon-si (KR)

(21) Appl. No.: 18/244,546

(22) Filed: Sep. 11, 2023

(30) Foreign Application Priority Data
Oct. 18, 2022 (KR) 10-2022-0133695
Nov. 29, 2022 (KR) 10-2022-0162248

(51) Int. Cl. H10B 80/00; H01L 23/00; H01L 23/498; H01L 23/538; H01L 25/10

(52) U.S. Cl. CPC H10B 80/00; H01L 23/49816; H01L 23/5383; H01L 23/5385; H01L 23/562; H01L 24/16; H01L 25/105; H01L 2224/16227

(57) ABSTRACT

A semiconductor package includes: a first redistribution layer including a first insulating layer and a first conductive pattern disposed in the first insulating layer; a first connection terminal disposed on a first surface of the first redistribution layer; a stacked memory module disposed on second surface of the first redistribution layer; a second redistribution layer disposed on the stacked memory module, and including a second insulating layer and a second conductive pattern disposed in the second insulating layer; a first bump disposed on a first surface of the second redistribution layer, and in contact with the stacked memory module; a first semiconductor chip disposed on second surface of the second redistribution layer; and a dummy structure disposed between the first redistribution layer and the second redistribution layer and spaced apart from the stacked memory module.

### CROSS-REFERENCE TO RELATED APPLICATION

This application claims priority under 35 USC § 119 to Korean Patent Application No. 10-2022-0133695 filed on Oct. 18, 2022 and Korean Patent Application No. 10-2022-0162248 filed on Nov. 29, 2022, the disclosures of which are incorporated by reference herein in their entireties.

### TECHNICAL FIELD

The present inventive concept relates to a semiconductor package, and more particularly, to a semiconductor package including a three-dimensional stacked memory module.

### DISCUSSION OF THE RELATED ART

With the development of the electronic industry, desire for electronic components that have high functionality and high-speed and that are miniaturized has increased. In response to this trend, a method of stacking or packaging various semiconductor chips on one package substrate or a method of stacking a package on another package may be used. For example, a package-in-package (PIP) type semiconductor package, a package-on-package (POP) type semiconductor package, or three-dimensional semiconductor packages including memory cells, which are three-dimensionally stacked, have been under development.

### SUMMARY

According to an embodiment of the present inventive concept, a semiconductor package includes: a first redistribution layer including a first insulating layer and a first conductive pattern disposed in the first insulating layer; a first connection terminal disposed on a first surface of the first redistribution layer; a stacked memory module disposed on second surface of the first redistribution layer; a second redistribution layer disposed on the stacked memory module, and including a second insulating layer and a second conductive pattern disposed in the second insulating layer; a first bump disposed on a first surface of the second redistribution layer, and in contact with the stacked memory module; a first semiconductor chip disposed on second surface of the second redistribution layer; and a dummy structure disposed between the first redistribution layer and the second redistribution layer and spaced apart from the stacked memory module.

According to an embodiment of the present inventive concept, a semiconductor package includes: a first redistribution layer including a first insulating layer and a first conductive pattern disposed in the first insulating layer; a first connection terminal disposed on the first redistribution layer; a stacked memory module disposed on the first redistribution layer; a second redistribution layer disposed on the stacked memory module, and including a second insulating layer and a second conductive pattern disposed in the second insulating layer; a first semiconductor chip disposed on the second redistribution layer; a first bump disposed on the first semiconductor chip, and electrically connecting the first semiconductor chip with the second redistribution layer; and a dummy structure disposed between the first redistribution layer and the second redistribution layer and spaced apart from the stacked memory module.

According to an embodiment of the present inventive concept, a semiconductor package includes: a first redistribution layer including a first insulating layer and a first conductive pattern disposed in the first insulating layer; a first connection terminal disposed on a bottom surface of the first redistribution layer and electrically connected to a main board; a stacked memory module disposed on an upper surface of the first redistribution layer; a second redistribution layer disposed on the stacked memory module, and including a second insulating layer and a second conductive pattern disposed in the second insulating layer; a first bump disposed on a bottom surface of the second redistribution layer, and in contact with the stacked memory module, wherein the first bump includes a first pillar layer and a first solder layer, wherein the first pillar layer is disposed on the bottom surface of the second redistribution layer, and the first solder layer is disposed on the first pillar layer; a first semiconductor chip disposed on an upper surface of the second redistribution layer; a via disposed between the first redistribution layer and the second redistribution layer; and a plurality of dummy structures disposed between the first redistribution layer and the second redistribution layer and disposed around the stacked memory module, wherein each of the plurality of dummy structures is in contact with the upper surface of the first redistribution layer and the bottom surface of the second redistribution layer.

### BRIEF DESCRIPTION OF THE DRAWINGS

The above and features of the present inventive concept will become more apparent by describing in detail exemplary embodiments thereof with reference to the attached drawings, in which:

FIG. 1 is a view illustrating an electronic device according to an embodiment of the present inventive concept.

FIG. 2 is a view illustrating an electronic device according to an embodiment of the present inventive concept.

FIG. 3 is a view illustrating a semiconductor package and a main board of FIG. 2.

FIG. 4 is a plan view illustrating a semiconductor package according to an embodiment of the present inventive concept.

FIG. 5 is an exploded perspective view illustrating a semiconductor package according to an embodiment of the present inventive concept.

FIG. 6 is a cross-sectional view illustrating a semiconductor package according to an embodiment of the present inventive concept.

FIG. 7 is a cross-sectional view illustrating a semiconductor package according to an embodiment of the present inventive concept.

FIG. 8 is a view illustrating a semiconductor package according to an embodiment of the present inventive concept.

FIGS. 9 and 10 are views illustrating a semiconductor package according to an embodiment of the present inventive concept.

FIG. 11 is a view illustrating a semiconductor package according to an embodiment of the present inventive concept.

FIG. 12 is a view illustrating a semiconductor package according to an embodiment of the present inventive concept.

FIGS. 13, 14, 15, 16, 17, and 18 are views illustrating intermediate steps to describe a method of manufacturing the semiconductor package of FIG. 6 according to an embodiment of the present inventive concept.

FIGS. 19, 20, 21, 22, 23 and 24 are views illustrating intermediate steps to describe a method of manufacturing the semiconductor package of FIG. 7 according to an embodiment of the present inventive concept.

### DETAILED DESCRIPTION OF THE EMBODIMENTS

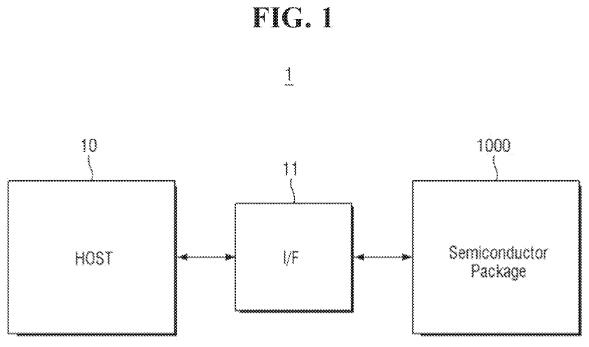

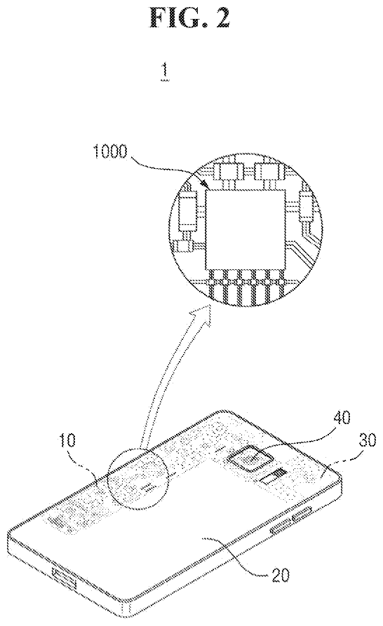

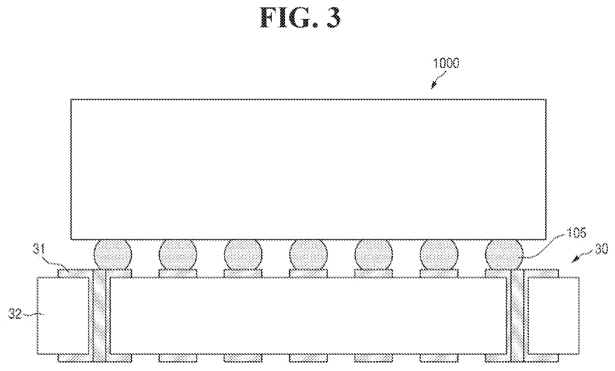

FIG. 1 is a view illustrating an electronic device according to an embodiment of the present inventive concept. FIG. 2 is a view illustrating an electronic device according to an embodiment of the present inventive concept. FIG. 3 is a view illustrating a semiconductor package and a main board of FIG. 2.

Referring to FIG. 1, an electronic device 1 may include a host 10, an interface 11 and a semiconductor package 1000.

In an embodiment of the present inventive concept, the host 10 may be connected with the semiconductor package 1000 through the interface 11. For example, the host 10 may transfer a signal to the semiconductor package 1000 to control the semiconductor package 1000. For example, the host 10 may receive the signal from the semiconductor package 1000 so that data included in the signal may be processed.

For example, the host 10 may include a central processing unit (CPU), a controller or an application specific integrated circuit (ASIC). In addition, for example, the host 10 may include a memory chip such as a dynamic random access memory (DRAM), a static RAM (SRAM), a phase-change RAM (PRAM), a magneto-resistive RAM (MRAM), a ferroelectric RAM (FeRAM) and a resistive RAM (RRAM).

Referring to FIGS. 1 and 2, the electronic device 1 may include a host 10, a body 20, a main board 30, a camera module 40 and a semiconductor package 1000.

The main board 30 may be disposed in the body 20 of the electronic device 1. The host 10, the camera module 40 and the semiconductor package 1000 may be disposed on the main board 30. The host 10, the camera module 40 and the semiconductor package 1000 may be electrically connected to one another by the main board 30. For example, the interface 11 may be implemented by the main board 30.

The host 10 and the semiconductor package 1000 may be electrically connected to each other by the main board 30 to transmit and receive a signal to and from each other.

Referring to FIG. 3, the semiconductor package 1000 may be disposed on the main board 30. For example, a first connection terminal 105 may be disposed on the main board 30. For example, the main board 30 may be connected with the semiconductor package 1000 by the first connection terminal 105.

The main board 30 may be a printed circuit wiring structure (or printed circuit board (PCB)), a ceramic wiring structure, a glass wiring structure, etc., but the present inventive concept is not limited thereto. For convenience of description and as an example, it is assumed that the main board 30 is a printed circuit wiring structure.

The main board 30 may include a connection structure 31 and a core 32. The core 32 may include, for example, a copper clad laminate (CCL), a PPG, an Ajinomoto Build-up Film (ABF), epoxy, polyimide and the like. The connection structure 31 may include at least one of, for example, copper (Cu), aluminum (Al), silver (Ag), tin (Sn), gold (Au), nickel (Ni), lead (Pb), titanium (Ti) or their alloy, but the present inventive concept is not limited thereto.

The core 32 may be disposed at the center of the main board 30 and the connection structure 31 may be disposed at upper and lower portions of the core 32. The connection structure 31 may be disposed to be exposed at upper and lower portions of the main board 30.

The connection structure 31 may be disposed to pass through the core 32. The connection structure 31 may electrically connect elements, which are in contact with the main board 30, with each other. For example, the connection structure 31 may electrically connect the semiconductor package 1000 with the host 10. For example, the connection structure 31 may electrically connect the semiconductor package 1000 with the host 10 through the first connection terminal 105.

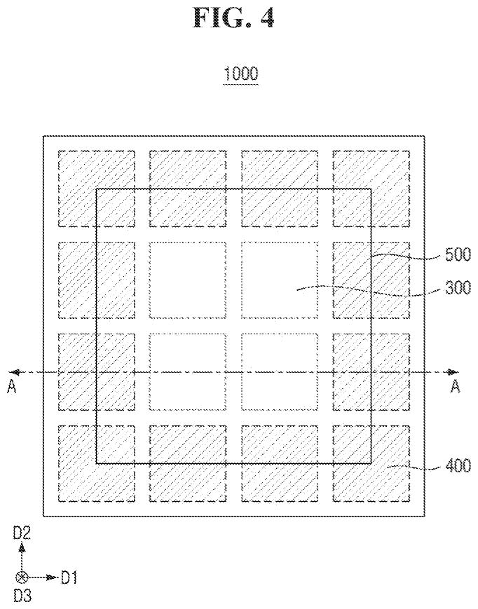

Hereinafter, a semiconductor package according to some embodiments will be described with reference to FIGS. 4 to 6.

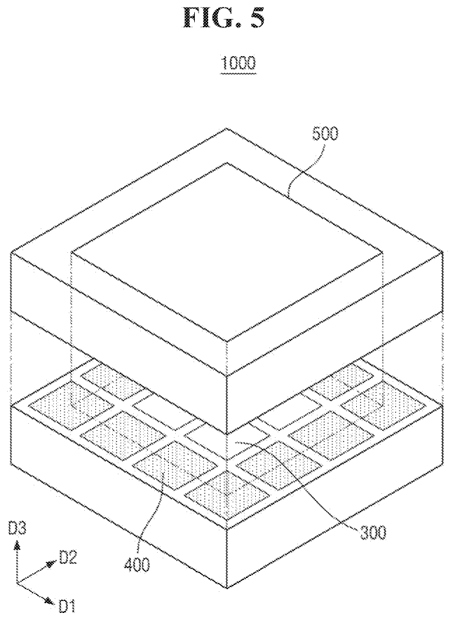

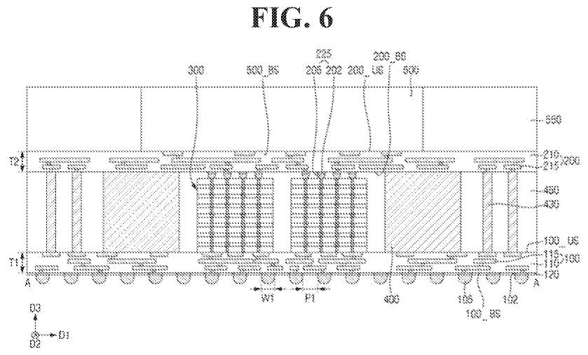

FIG. 4 is a plan view illustrating a semiconductor package according to an embodiment of the present inventive concept. FIG. 5 is an exploded perspective view illustrating a semiconductor package according to an embodiment of the present inventive concept. FIG. 6 is a cross-sectional view illustrating a semiconductor package according to an embodiment of the present inventive concept. For reference, FIG. 6 is a cross-sectional view taken along line A-A of FIG. 4.

Referring to FIGS. 4 to 6, the semiconductor package according to an embodiment of the present inventive concept may include a first redistribution layer 100, a first connection terminal 105, a stacked memory module 300, a second redistribution layer 200, a first bump 225, a first semiconductor chip 500 and a dummy structure 400.

The first redistribution layer 100 may include a first insulating layer 110 and a first conductive pattern 115. The first redistribution layer 100 may include an upper surface 100_US and a bottom surface 100_BS, which are opposite to each other.

The first conductive pattern 115 may be formed in the first insulating layer 110. The first insulating layer 110 and the first conductive pattern 115 may constitute a wiring pattern for electrically connecting a first pad 102 with the stacked memory module 300. In addition, the first insulating layer 110 and the first conductive pattern 115 may constitute a wiring pattern for electrically connecting the first pad 102 with a via 430. The first conductive pattern 115 might not be electrically connected to the dummy structure 400.

The first insulating layer 110 is illustrated as a single layer, but this is an example and the present inventive concept is not limited thereto. For example, the first insulating layer 110 may be composed of multiple layers so that the first conductive pattern 115 of multiple layers can be formed in the first insulating layer 110. The first conductive pattern 115 may include, for example, a metal material that includes copper (Cu), aluminum (Al), silver (Ag), tin (Sn), gold (Au), nickel (Ni), lead (Pb), titanium (Ti) or their alloy.

The first redistribution layer 100 may have a first thickness T1 in a third direction D3. The first thickness T1 may be a distance from the bottom surface 100_BS to the upper surface 100_US of the first redistribution layer 100 in the third direction D3. In this case, the third direction D3 may be a direction substantially perpendicular to the upper surface 100_US of the first redistribution layer 100. A first direction D1 and a second direction D2 may be parallel with the upper surface 100_US of the first redistribution layer 100. The first thickness T1 of the first redistribution layer 100 may be about 30 μm to about 1000 μm.

A passivation layer 120 and the first pad 102 may be formed on the bottom surface 100_BS of the first redistribution layer 100. The first pad 102 may be electrically connected to the first conductive pattern 115. The passivation layer 120 may cover the bottom surface of the first redistribution layer 100 and expose the first pad 102.

The passivation layer 120 may include, for example, a photoimageable dielectric (PID) material, but the present inventive concept is not limited thereto. The first pad 102 may include, for example, a metal material such as copper (Cu) or aluminum (Al), but is not limited thereto.

In an embodiment of the present inventive concept, the first connection terminal 105 may be formed on the bottom surface 100_BS of the first redistribution layer 100. For example, the first connection terminal 105 may be attached to the first pad 102. The first connection terminal 105 may be, for example, spherical or elliptical, but the present inventive concept is not limited thereto.

The first connection terminal 105 may have a first width W1. The first width W1 may be the largest width in the first direction D1 or the second direction D2 of the first connection terminal 105. The first width W1 may be about 100 μm to about 150 μm.

The first connection terminal 105 may be provided as a plurality of first connection terminals 105. The plurality of first connection terminals 105 may be arranged in the first direction D1 and the second direction D2. The first connection terminals 105 adjacent to each other may be spaced apart from each other as much as a first pitch P1. For example, the plurality of first connection terminals 105 may be aligned to be spaced apart from each other as much as the first pitch P1 in the first direction D1. The first pitch P1 may be about 50 μm to about 75 μm.

The first connection terminal 105 may include, for example, at least one of tin (Sn), indium (In), lead (Pb), zinc (Zn), nickel (Ni), gold (Au), silver (Ag), copper (Cu), antimony (Sb), bismuth (Bi) or their combination, but the present inventive concept is not limited thereto.

The first connection terminal 105 may electrically connect the first redistribution layer 100 with an external device. Therefore, the first connection terminal 105 may provide an electrical signal to the first redistribution layer 100 or provide the electrical signal provided from the first redistribution layer 100 to the external device.

The stacked memory module 300 may be disposed on the first redistribution layer 100. For example, the stacked memory module 300 may be directly in contact with the first redistribution layer 100. The stacked memory module 300 may be electrically connected to the first redistribution layer 100. Therefore, the stacked memory module 300 may receive the electrical signal provided from the first redistribution layer 100.

The stacked memory module 300 may be, for example, a high bandwidth memory (HBM), but the present inventive concept is not limited thereto. The stacked memory module 300 may be a memory module implemented based on GDDR, HMC, or Wide I/O standard. In the following description, as an example, it is assumed that the stacked memory module 300 is a high bandwidth memory module.

The stacked memory module 300 may include a buffer die, a plurality of DRAM dies, and conductive means connecting the respective dies with each other. The buffer die may perform communication with the first semiconductor chip 500 through the second redistribution layer 200 that receives the signal transferred from the first redistribution layer 100. The conductive means may be formed, for example, in a copper (Cu)-copper (Cu) bonding or low-temperature direct bond interconnect manner.

The second redistribution layer 200 may include a second insulating layer 210 and a second conductive pattern 215. The second redistribution layer 200 may include an upper surface 200_US and a bottom surface 200_BS, which are opposite to each other. The bottom surface 200_BS of the second redistribution layer 200 and the upper surface 100_US of the first redistribution layer 100 may face each other.

The second conductive pattern 215 may be formed in the second insulating layer 210. The second insulating layer 210 and the second conductive pattern 215 may constitute a wiring pattern for electrically connecting the first bump 225 with the first semiconductor chip 500. In addition, the second insulating layer 210 and the second conductive pattern 215 may constitute a wiring pattern for electrically connecting the first semiconductor chip 500 with the via 430. The second conductive pattern 215 might not be electrically connected to the dummy structure 400.

The second insulating layer 210 is illustrated as a single layer, but this is an example and the present inventive concept is not limited thereto. For example, the second insulating layer 210 may be composed of multiple layers, and the second conductive pattern 215 including multiple layers may be formed in the second insulating layer 210.

The second redistribution layer 200 may have a second thickness T2 in the third direction D3. The second thickness T2 may be a distance from the bottom surface 200_BS to the upper surface 200_US of the second redistribution layer 200 in the third direction D3. The second thickness T2 of the second redistribution layer 200 may be about 30 μm to about 1000 μm.

A lower passivation layer may be further provided on the bottom surface 200_BS of the second redistribution layer 200. The lower passivation layer may cover the bottom surface 200_BS of the second redistribution layer 200 and expose a first pillar layer 202.

The first bump 225 may be formed on the bottom surface 200_BS of the second redistribution layer 200. The first bump 225 may be disposed on the stacked memory module 300. For example, the first bump 225 may be directly in contact with the stacked memory module 300. The stacked memory module 300 and the second redistribution layer 200 may be electrically connected to each other through the first bump 225. Therefore, the stacked memory module 300 may transmit and receive the electrical signal to and from the first semiconductor chip 500 through the second redistribution layer 200.

The first bump 225 may include, for example, a first pillar layer 202 and a first solder layer 205.

The first pillar layer 202 may be protruded from the bottom surface 200_BS of the second redistribution layer 200. The first pillar layer 202 may include, for example, copper (Cu), a copper alloy, nickel (Ni), a nickel alloy, palladium (Pd), platinum (Pt), gold (Au), cobalt (Co) or their combination, but the present inventive concept is not limited thereto.

The first solder layer 205 may connect the first pillar layer 202 with the stacked memory module 300. The first solder layer 205 may be, for example, spherical or elliptical, but the present inventive concept is not limited thereto. The first solder layer 205 may include, for example, tin (Sn), indium (In), bismuth (Bi), antimony (Sb), copper (Cu), silver (Ag), zinc (Zn), lead (Pb) or their combination, but the present inventive concept is not limited thereto.

The dummy structure 400 may be disposed to be spaced apart from the stacked memory module 300 on the first redistribution layer 100. The dummy structure 400 may be disposed between the first redistribution layer 100 and the second redistribution layer 200. For example, the dummy structure 400 may be directly in contact with the upper surface 100_US of the first redistribution layer 100 and the bottom surface 200_BS of the second redistribution layer 200. A height of the dummy structure 400 in the third direction D3 may be higher than that of the stacked memory module 300.

The dummy structure 400 might not be electrically connected to the first redistribution layer 100 and the second redistribution layer 200. For example, the dummy structure 400 may include silicon (Si). The dummy structure 400 may prevent warpage of the second redistribution layer 200 from occurring.

A first mold layer 450 may be formed on the first redistribution layer 100. The first mold layer 450 may fill a space between the stacked memory module 300 and the dummy structure 400. In addition, the first mold layer 450 may fill a space between the respective stacked memory modules 300 and a space between the respective dummy structures 400. Therefore, the first mold layer 450 may cover and protect the first redistribution layer 100, the stacked memory module 300 and the dummy structure 400. For example, the first mold layer 450 may be disposed between the first redistribution layer 100 and the second redistribution layer 200.

The first mold layer 450 may include, for example, an insulating polymer material such as an epoxy molding compound (EMC). The first mold layer 450 may include a thermosetting resin such as an epoxy resin, a thermoplastic resin such as polyimide, or a resin including a reinforcing material, such as a filler, in the thermosetting resin or the thermoplastic resin, for example, ABF, FR-4, BT resin, etc.

The filler may be at least one of, for example, silica (SiO₂), alumina (Al₂O₃), silicon carbide (SiC), barium sulfate (BaSO₄), talc, mud, mica powder, aluminum hydroxide (Al(OH)₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and/or zircon calcium (CaZrO₃), but its material is not limited thereto and may include a metal material and/or an organic material.

The via 430 may electrically connect the first redistribution layer 100 with the second redistribution layer 200 by passing through the first mold layer 450. The via 430 may be spaced apart from the dummy structure 400. Although two vias 430 are illustrated as being disposed at one side of the dummy structure 400, this is an example. Various modifications may be made in the number of vias 430. The via 433 may include a metal material that includes, for example, copper (Cu), aluminum (Al), silver (Ag), tin (Sn), gold (Au), nickel (Ni), lead (Pb), titanium (Ti) or their alloy.

The stacked memory module 300 and the dummy structure 400 will be described with reference to FIGS. 4 and 5.

In a plan view, the stacked memory module 300 may be disposed at the center of the first redistribution layer 100. The number of stacked memory modules 300 is illustrated as being four, but the present inventive concept is not limited thereto.

In an embodiment of the present inventive concept, the first semiconductor chip 500 completely overlaps the stacked memory module 300 in the third direction D3, but the present inventive concept is not limited thereto. For example, when a plurality of first semiconductor chips 500 are provided, the stacked memory module 300 may overlap a portion of the first semiconductor chips 500.

The dummy structure 400 may be disposed around the stacked memory module 300. The dummy structure 400 may be disposed outside the stacked memory module 300 to protect the stacked memory module 300 from an external impact. The number of dummy structures 400 is illustrated as being 12, but the present inventive concept is not limited thereto.

Although a width of the stacked memory module 300 and a width of the dummy structure 400 are illustrated as being the same as each other in the first direction D1 and the second direction D2, this is an example. For example, the width of the dummy structure 400 may be greater than or smaller than that of the stacked memory module 300.

Referring back to FIG. 6, the first semiconductor chip 500 may be disposed on the second redistribution layer 200. For example, the first semiconductor chip 500 may be disposed on the upper surface 200_US of the second redistribution layer 200. The first semiconductor chip 500 may be an integrated circuit (IC) in which hundreds to millions of semiconductor devices are integrated in one chip. For example, the first semiconductor chip 500 may be, but is not limited to, an application processor AP such as a Central Processing Unit (CPU), a Graphic Processing Unit (GPU), a Field Programmable Gate Array (FPGA), a digital signal processor, an encryption processor, a microprocessor and a microcontroller. For example, the first semiconductor chip 500 may be a logic chip such as an analog-digital converter (ADC) or an application-specific IC (ASIC), or may be a memory chip such as a volatile memory (e.g., DRAM) or a non-volatile memory (e.g., ROM or flash memory). In addition, the first semiconductor chip 500 may be composed of a combination of the logic chip and the memory chip.

A second mold layer 550 may be formed on the second redistribution layer 200. The second mold layer 550 may be formed around the first semiconductor chip 500. Therefore, the second mold layer 550 may protect the first semiconductor chip 500. For example, the second mold layer 550 may cover the first semiconductor chip 500. For example, the second mold layer 550 may cover an upper surface of the first semiconductor chip 500. As another example, the second mold layer 550 may expose the upper surface of the first semiconductor chip 500. The description of the material of the second mold layer 550 may be similar to that of the first mold layer 450.

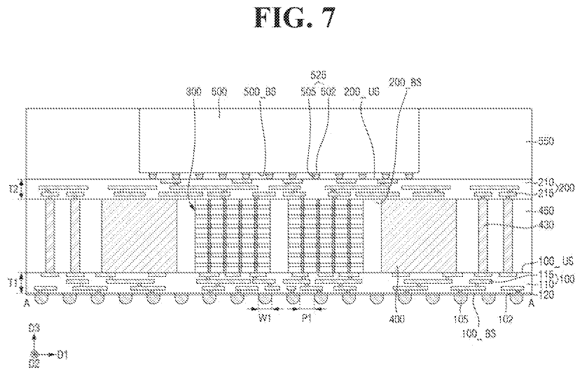

FIG. 7 is a cross-sectional view illustrating a semiconductor package according to an embodiment of the present inventive concept. For convenience of description, the following description will be based on differences from those described with reference to FIGS. 4 to 6. Redundant or repetitive descriptions may be omitted or briefly discussed.

Referring to FIG. 7, the semiconductor package according to an embodiment of the present inventive concept may include a first redistribution layer 100, a first connection terminal 105, a stacked memory module 300, a second redistribution layer 200, a first semiconductor chip 500, a second bump 525 and a dummy structure 400. The description of the first redistribution layer 100 and the first connection terminal 105 may be the same as that of FIG. 6.

The stacked memory module 300 may be disposed on the first redistribution layer 100. The stacked memory module 300 may be, for example, a high bandwidth memory (HBM). The stacked memory module 300 may be directly in contact with the bottom surface 200_BS of the second redistribution layer 200. The stacked memory module 300 may receive an electrical signal from the first redistribution layer 100 and transmit the electrical signal to the second redistribution layer 200.

The dummy structure 400 may be disposed to be spaced apart from the stacked memory module 300 on the first redistribution layer 100. The dummy structure 400 may be disposed between the first redistribution layer 100 and the second redistribution layer 200. The dummy structure 400 may be directly in contact with the upper surface 100_US of the first redistribution layer 100 and the bottom surface 200_BS of the second redistribution layer 200. A height of the dummy structure 400 in the third direction D3 may be the same as that of the stacked memory module 300.

The first semiconductor chip 500 may be disposed on the upper surface 200_US of the second redistribution layer 200. In an embodiment of the present inventive concept, the first semiconductor chip 500 may be disposed on the second redistribution layer 200 by a flip chip bonding method. For example, the second bump 525 may be formed between the upper surface 200_US of the second redistribution layer 200 and a bottom surface 500_BS of the first semiconductor chip 500. The second bump 525 may electrically connect the second redistribution layer 200 with the first semiconductor chip 500.

The second bump 525 may include, for example, a second pillar layer 502 and a second solder layer 505.

The first pillar layer 502 may be protruded from the bottom surface 500_BS of the first semiconductor chip 500. The second pillar layer 502 may include, for example, copper (Cu), a copper alloy, nickel (Ni), a nickel alloy, palladium (Pd), platinum (Pt), gold (Au), cobalt (Co) and their combination, but the present inventive concept is not limited thereto.

The second solder layer 505 may connect the second pillar layer 502 with the second redistribution layer 200. The second solder layer 505 may be, for example, spherical or elliptical, but the present inventive concept is not limited thereto. The second solder layer 505 may include, for example, tin (Sn), indium (In), bismuth (Bi), antimony (Sb), copper (Cu), silver (Ag), zinc (Zn), lead (Pb) or their combination, but the present inventive concept is not limited thereto.

An underfill material may be formed between the first semiconductor chip 500 and the second redistribution layer 200. The underfill material may fill a region between the second redistribution layer 200 and the first semiconductor chip 500. The underfill material may prevent the first semiconductor chip 500 from being broken by fixing the first semiconductor chip 500 onto the second redistribution layer 200. The underfill material may cover the second bump 525. The second bump 525 may electrically connect the second redistribution layer 200 with the first semiconductor chip 500 by passing through the underfill material.

The underfill material may include, for example, an insulating polymer material such as an epoxy molding compound (EMC), but the present inventive concept is not limited thereto. In an embodiment of the present inventive concept, the underfill material may include a material different from that of the second mold layer 550. For example, the underfill material may include an insulating material having fluidity more excellent than that of the second mold layer 550. Therefore, the underfill material may efficiently fill a narrow space between the second redistribution layer 200 and the first semiconductor chip 500.

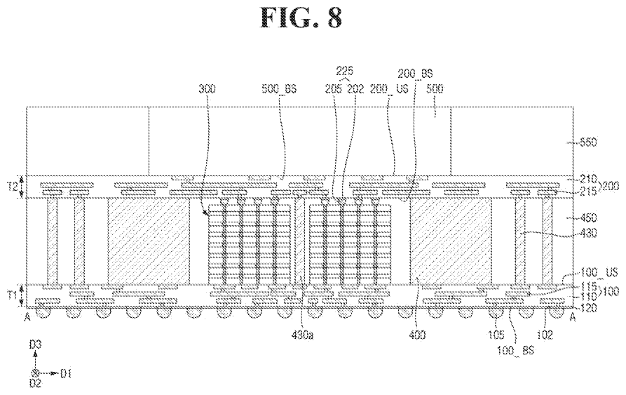

FIG. 8 is a view illustrating a semiconductor package according to an embodiment of the present inventive concept. For convenience of description, the following description will be based on differences from those described with reference to FIG. 6. Redundant or repetitive descriptions may be omitted or briefly discussed.

A plurality of vias 430 may be provided. The vias 430 may be disposed around the dummy structure 400. Some vias 430a may be disposed between the stacked memory modules 300, but the present inventive concept is not limited thereto. For example, some vias 430 may be disposed between the dummy structures 400, or may be disposed between the dummy structure 400 and the stacked memory module 300.

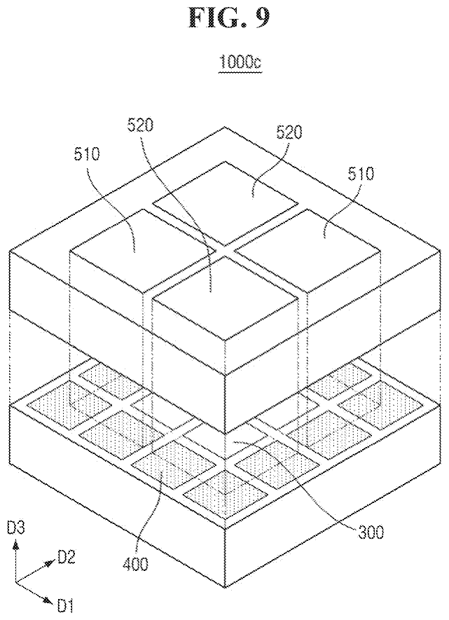

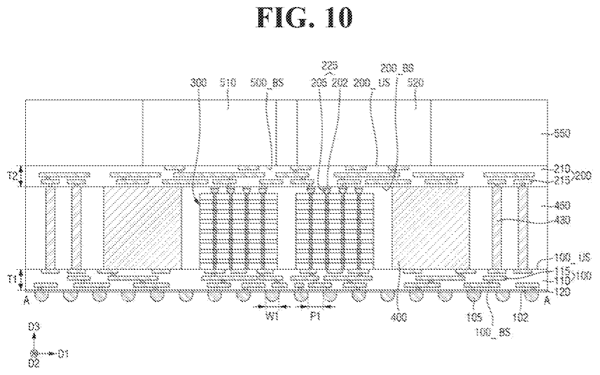

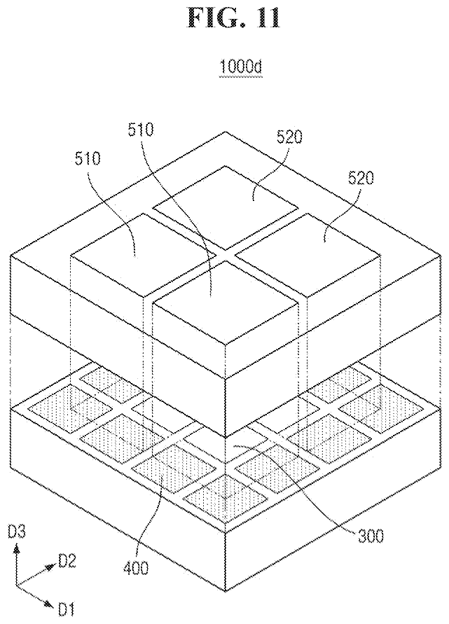

FIGS. 9 and 10 are views illustrating a semiconductor package according to an embodiment of the present inventive concept. FIG. 11 is a view illustrating a semiconductor package according to an embodiment of the present inventive concept. For convenience of description, the following description will be based on differences from those described with reference to FIGS. 4 to 6. Redundant or repetitive descriptions may be omitted or briefly discussed.

Referring to FIGS. 9 to 11, the semiconductor package 1000 may include a second semiconductor chip 510 and a third semiconductor chip 520 instead of the first semiconductor chip 500 of FIG. 6.

In an embodiment of the present inventive concept, the second semiconductor chip 510 may be arranged in the first direction D1 or the second direction D2 as shown in FIG. 9. In an embodiment of the present inventive concept, as shown in FIG. 11, the second semiconductor chip 510 and the third semiconductor chip 530 may be arranged in parallel in the first direction D1.

Each of the second semiconductor chip 510 and the third semiconductor chip 520 may be an integrated circuit (IC) in which hundreds to millions of semiconductor devices are integrated in one chip. For example, each of the second semiconductor chip 510 and the third semiconductor chip 520 may be an application processor (AP) such as a central processing unit (CPU), a graphic processing unit (GPU), a field-programmable gate array (FPGA), a digital signal processor, an encryption processor, a microprocessor and a microcontroller, but is not limited thereto. For example, each of the second semiconductor chip 510 and the third semiconductor chip 520 may be a logic chip such as an analog-digital converter (ADC) or an application-specific IC (ASIC), or may be a memory chip such as a volatile memory (e.g., DRAM) or a non-volatile memory (e.g., ROM or flash memory). The second semiconductor chip 510 and the third semiconductor chip 520 may be the same as or different from each other. For example, the second semiconductor chip 510 may be a CPU, and the third semiconductor chip 530 may be a GPU.

In an embodiment of the present inventive concept, each of the second semiconductor chip 510 and the third semiconductor chip 520 may be a chiplet. In this case, the second semiconductor chip 510 and the third semiconductor chip 520 may constitute one processor.

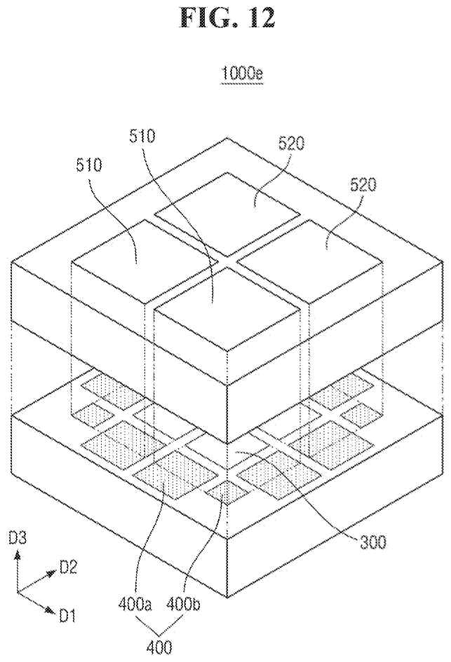

FIG. 12 is a view illustrating a semiconductor package according to an embodiment of the present inventive concept. For convenience of description, the following description will be based on differences from those described with reference to FIGS. 4 to 6 and FIG. 11. Redundant or repetitive descriptions may be omitted or briefly discussed.

Referring to FIG. 12, the dummy structure 400 may include a first sub-dummy structure 400a and a second sub-dummy structure 400b. A width of the first sub-dummy structure 400a may be greater than that of the second sub-dummy structure 400b. In this case, the width refers to a width in the first direction D1 or the second direction D2. The second sub-dummy structure 400b may be disposed adjacent to a corner of the first redistribution layer 100 in a plan view, but the present inventive concept is not limited thereto. As the second sub-dummy structure 400b is disposed adjacent to the corner, warpage of the semiconductor package 1000e may be avoided.

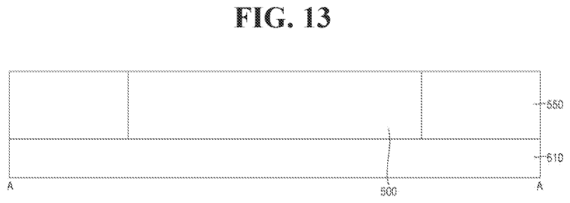

FIGS. 13 to 18 are views illustrating intermediate steps to describe a method of manufacturing the semiconductor package of FIG. 6 according to an embodiment of the present inventive concept.

Referring to FIG. 13, a first semiconductor chip 500 may be disposed on a first substrate 610. Then, the first semiconductor chip 500 may be covered using a molding material (e.g., EMC). A second mold layer 550 may be formed on the first semiconductor chip 500 by grinding the molding material. The first substrate 610 may include glass or an organic material. A surface of the first semiconductor chip 500, which is in contact with the first substrate 610, may be a rear surface of the first semiconductor chip 500. The rear surface of the first semiconductor chip 500 may be a surface having a passivation layer, and the front surface of the first semiconductor chip 500 may be a surface where a semiconductor device such as CMOS exists.

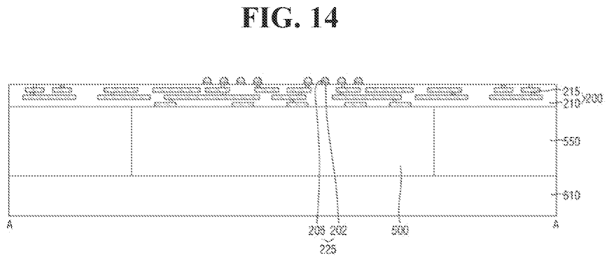

Referring to FIG. 14, a second redistribution layer 200 may be formed on the first semiconductor chip 500. The second redistribution layer 200 may include a second insulating layer 210 and a second conductive pattern 215 in the second insulating layer 210. The second insulating layer 210 may be formed by coating and curing a photosensitive resin (e.g., PID) on a carrier, and the second conductive pattern 215 may be formed using a photo process, an etching process, a plating process or the like. Subsequently, a first bump 225 may be formed on the second redistribution layer 200. The first bump 225 may be formed only in a region where the stacked memory module 300 is disposed.

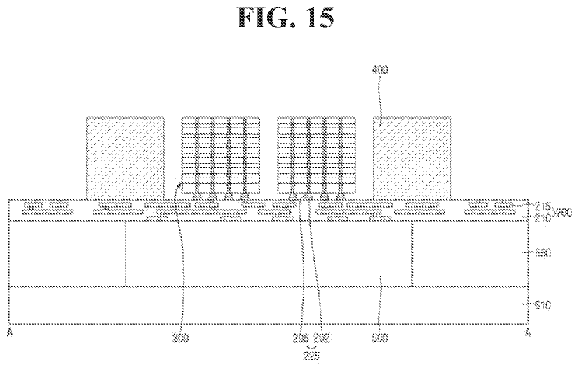

Referring to FIG. 15, the stacked memory module 300 may be disposed on the first bump 225. The stacked memory module 300 may be connected to the first bump 225 to transmit an electrical signal to and from the second redistribution layer 220. A dummy structure 400 may be formed on the second redistribution layer 220. The dummy structure 400 may be spaced apart from the stacked memory module 300. In an embodiment of the present inventive concept, the dummy structure 400 may be disposed around the stacked memory module 300.

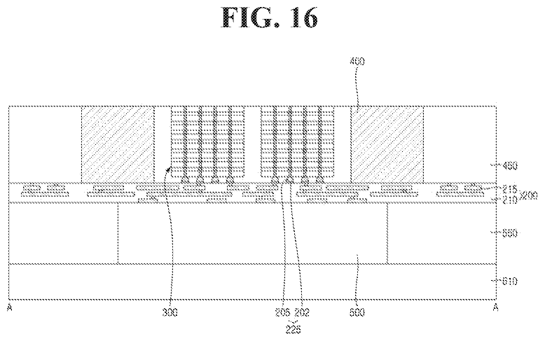

Referring to FIG. 16, a first mold layer 450 may be formed on the stacked memory module 300 and the dummy structure 400 by using a molding material (e.g., EMC). The first mold layer 450 may fill a space between the stacked memory module 300 and the dummy structure 400. The first mold layer 450 may cover the second redistribution layer 200 and expose the stacked memory module 300 and the dummy structure 400.

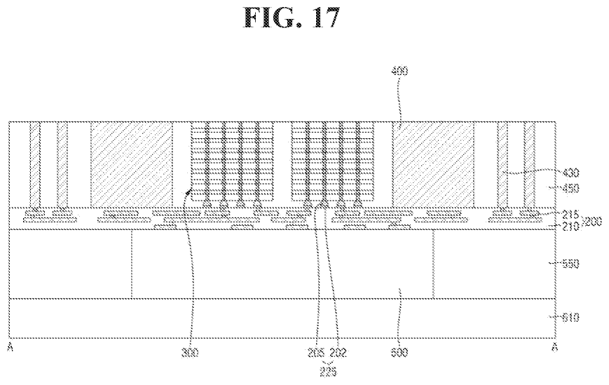

Referring to FIG. 17, a via 430 may be formed in the first mold layer 450 through an etching process and a plating process. The via 430 may be in contact with the second redistribution layer 200.

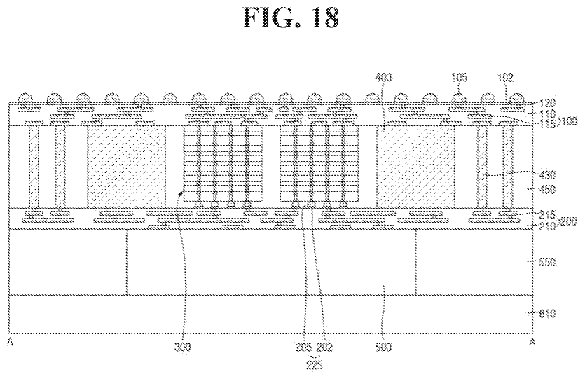

Referring to FIG. 18, a first redistribution layer 100 may be formed on the stacked memory module 300 and the dummy structure 400. The first redistribution layer 100 may include a first insulating layer 110 and a first conductive pattern 115 in the first insulating layer 110. The first insulating layer 110 may be formed by coating and curing a photosensitive resin (e.g., PID) on the carrier, and the first conductive pattern 115 may be formed using a photo process, an etching process, a plating process or the like.

A passivation layer 120 and a first pad 102 may be formed on the second redistribution layer 200. The passivation layer 120 may cover the second redistribution layer 200 and expose the first pad 102. Subsequently, a first connection terminal 105 may be formed on the first pad 102. The first connection terminal 105 may be, for example, spherical or elliptical, but the present inventive concept is not limited thereto. Then, the first substrate 610 is removed, so that the semiconductor package the same as that of FIG. 6 may be provided.

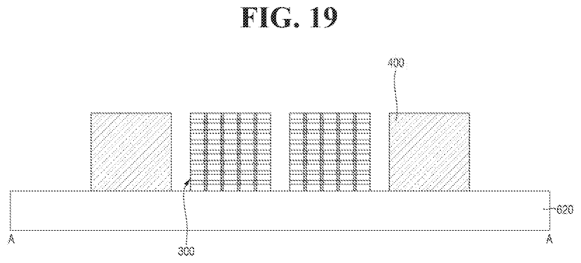

FIGS. 19 to 24 are views illustrating intermediate steps to describe a method of manufacturing the semiconductor package of FIG. 7 according to an embodiment of the present inventive concept.

Referring to FIG. 19, a stacked memory module 300 and a dummy structure 400 may be arranged on a second substrate 620. The dummy structure 400 may be disposed around the stacked memory module 300. The stacked memory module 300 may be formed, and the dummy structure 400 may be formed, but the present inventive concept is not limited thereto.

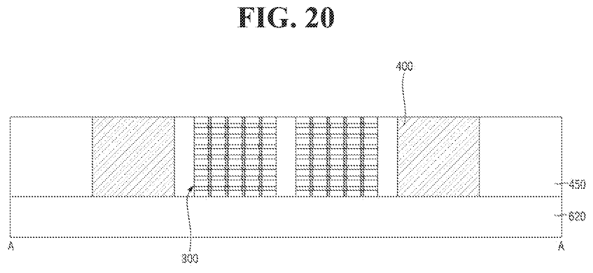

Referring to FIG. 20, a first mold layer 450 may be formed using a molding material (e.g., EMC) of the second substrate 620. The first mold layer 450 may fill a space between the stacked memory module 300 and the dummy structure 400. The first mold layer 450 may cover the second substrate 620 and expose the stacked memory module 300 and the dummy structure 400.

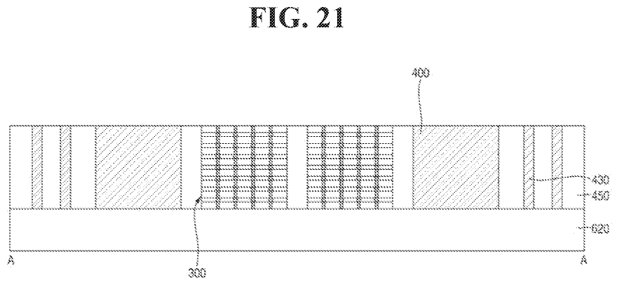

Referring to FIG. 21, a via 430 may be formed in the first mold layer 450 through an etching process and a plating process.

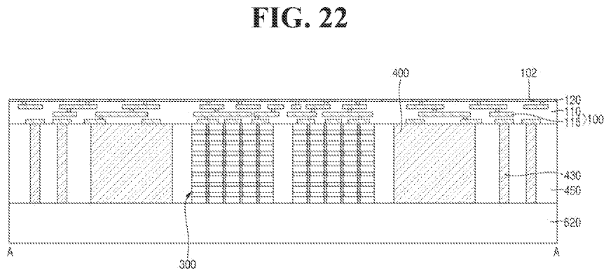

Referring to FIG. 22, a first redistribution layer 100 may be formed on the stacked memory module 300 and the dummy structure 400. The first redistribution layer 100 may include a first insulating layer 110 and a first conductive pattern 115 in the first insulating layer 110. The first insulating layer 110 may be formed by coating and curing a photosensitive resin (e.g., PID) on a carrier, and the first conductive pattern 115 may be formed using a photo process, an etching process, a plating process or the like.

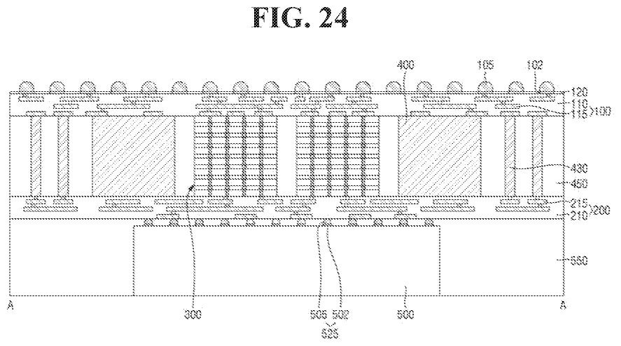

A passivation layer 120 and a first pad 102 may be formed on the first redistribution layer 100. The passivation layer 120 may cover the first redistribution layer 100 and expose the first pad 102, but the present inventive concept is not limited thereto. For example, unlike the illustrated example, the passivation layer 120 and the first pad 102 may be formed after a first semiconductor chip 500 of FIG. 24 is packaged.

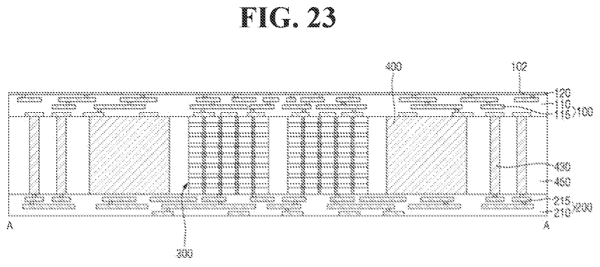

Referring to FIG. 23, the second substrate 620 may be removed, and the second redistribution layer 200 may be formed. The second substrate 620 may be removed by being de-bonded by a laser device. Then, a second insulating layer 210 and a second conductive pattern 215 may be formed in a place from which the second substrate 620 is removed. The second insulating layer 210 may be formed by coating and curing a photosensitive resin (e.g., PID) on the carrier, and the second conductive pattern 215 may be formed using a photo process, an etching process, a plating process or the like.

Referring to FIG. 24, the first semiconductor chip 500 may be disposed on the second redistribution layer 200, and a second mold layer 550 may be formed. A second bump 525 may be provided by being formed on the first semiconductor chip 500. In an embodiment of the present inventive concept, the first semiconductor chip 500 may be disposed on the second redistribution layer 200 by a flip chip bonding method. Subsequently, the second mold layer 550 may be formed around the first semiconductor chip 500 by using a molding material (e.g., EMC). In an embodiment of the present inventive concept, an underfill material may be formed between the first semiconductor chip 500 and the second redistribution layer 200 before the second mold layer 550 is formed.

Subsequently, a first connection terminal 105 may be formed on the first pad 102. The first connection terminal 105 may be, for example, spherical or elliptical, but the present inventive concept is not limited thereto.

While the present inventive concept has been described with reference to exemplary embodiments thereof, it will be understood by those of ordinary skill in the art that various changes in form and details may be made thereto without departing from the spirit and scope of the present inventive concept.

What is claimed is:

1. A semiconductor package comprising:
a first redistribution layer including a first insulating layer and a first conductive pattern disposed in the first insulating layer;
a first connection terminal disposed on a first surface of the first redistribution layer;
a stacked memory module disposed on second surface of the first redistribution layer;
a second redistribution layer disposed on the stacked memory module, and including a second insulating layer and a second conductive pattern disposed in the second insulating layer;
a first bump disposed on a first surface of the second redistribution layer, and in contact with the stacked memory module;
a first semiconductor chip disposed on second surface of the second redistribution layer; and
a dummy structure disposed between the first redistribution layer and the second redistribution layer and spaced apart from the stacked memory module.

2. The semiconductor package of claim 1, wherein the first connection terminal is arranged as a plurality of first connection terminals, and a distance between the plurality of first connection terminals is about 50 μm to about 75 μm.

3. The semiconductor package of claim 1, wherein a width of the first connection terminal is about 100 μm to about 150 μm in a direction parallel with the second surface of the first redistribution layer.

4. The semiconductor package of claim 1, further comprising a via disposed between the first redistribution layer and the second redistribution layer,
wherein the via electrically connects the first redistribution layer with the second redistribution layer.

5. The semiconductor package of claim 1, wherein the dummy structure is in contact with the first surface of the second redistribution layer and the second surface of the first redistribution layer.

6. The semiconductor package of claim 1, wherein the first redistribution layer includes a passivation layer covering the first surface of the first redistribution layer, wherein a first pad is exposed from the passivation layer, and
the first connection terminal is disposed on the first pad.

7. The semiconductor package of claim 1, wherein the dummy structure is provided as a plurality of dummy structures, and
the plurality of dummy structures are disposed around the stacked memory module.

8. The semiconductor package of claim 1, further comprising a second semiconductor chip disposed on the second redistribution layer and disposed at one side of the first semiconductor chip,
wherein the first semiconductor chip is different from the second semiconductor chip.

9. The semiconductor package of claim 1, wherein the dummy structure includes a first sub-dummy structure and a second sub-dummy structure, and
a width of the first sub-dummy structure is greater than a width of the second sub-dummy structure in a direction parallel with the second surface of the first redistribution layer.

10. The semiconductor package of claim 1, wherein a thickness of the first redistribution layer is about 30 μm to about 1000 μm in a direction perpendicular to the second surface of the first redistribution layer.

11. The semiconductor package of claim 1, wherein the first bump includes a first pillar layer and a first solder layer, wherein the first pillar layer is disposed on the first surface of the second redistribution layer, wherein the first solder layer is disposed on the first pillar layer, and
the first pillar layer is in contact with the stacked memory module.

12. The semiconductor package of claim 1, wherein the dummy structure includes silicon.

13. A semiconductor package comprising:
a first redistribution layer including a first insulating layer and a first conductive pattern disposed in the first insulating layer;
a first connection terminal disposed on the first redistribution layer;
a stacked memory module disposed on the first redistribution layer;
a second redistribution layer disposed on the stacked memory module, and including a second insulating layer and a second conductive pattern disposed in the second insulating layer;
a first semiconductor chip disposed on the second redistribution layer;
a first bump disposed on the first semiconductor chip, and electrically connecting the first semiconductor chip with the second redistribution layer; and
a dummy structure disposed between the first redistribution layer and the second redistribution layer and spaced apart from the stacked memory module.

14. The semiconductor package of claim 13, wherein the stacked memory module is in contact with a bottom surface of the second redistribution layer.

15. The semiconductor package of claim 13, wherein a height of the stacked memory module is a same as a height of the dummy structure in a direction perpendicular to an upper surface of the first redistribution layer.

16. The semiconductor package of claim 13, wherein a width of the first connection terminal is about 100 μm to about 150 μm in a direction parallel with an upper surface of the first redistribution layer.

17. The semiconductor package of claim 13, wherein a thickness of the first redistribution layer is about 30 μm to about 1000 μm in a direction perpendicular to an upper surface of the first redistribution layer.

18. The semiconductor package of claim 13, wherein the first connection terminal is arranged as a plurality of first connection terminals, and a distance between the plurality of first connection terminals is about 50 μm to about 75 μm.

19. The semiconductor package of claim 13, wherein the first bump includes a first pillar layer and a first solder layer, wherein the first pillar layer is disposed on a bottom surface of the first semiconductor chip, wherein the first solder layer is disposed on the first pillar layer, and
the first pillar layer is in contact with the second redistribution layer.

20. A semiconductor package comprising:
a first redistribution layer including a first insulating layer and a first conductive pattern disposed in the first insulating layer;
a first connection terminal disposed on a bottom surface of the first redistribution layer and electrically connected to a main board;
a stacked memory module disposed on an upper surface of the first redistribution layer;
a second redistribution layer disposed on the stacked memory module, and including a second insulating layer and a second conductive pattern disposed in the second insulating layer;
a first bump disposed on a bottom surface of the second redistribution layer, and in contact with the stacked memory module, wherein the first bump includes a first pillar layer and a first solder layer, wherein the first pillar layer is disposed on the bottom surface of the second redistribution layer, and the first solder layer is disposed on the first pillar layer;
a first semiconductor chip disposed on an upper surface of the second redistribution layer;
a via disposed between the first redistribution layer and the second redistribution layer; and
a plurality of dummy structures disposed between the first redistribution layer and the second redistribution layer and disposed around the stacked memory module,
wherein each of the plurality of dummy structures is in contact with the upper surface of the first redistribution layer and the bottom surface of the second redistribution layer.
